(19) United States
(12) Patent Application Publication
(10) Pub. No.: US 2013/0168709 A1
(43) Pub. Date: Jul. 4, 2013

(54) LIGHT EMITTING DIODE DEVICE WITH MULTIPLE LIGHT EMITTING DIODES

(71) Applicant: HSIN-CHIANG LIN, Hsinchu (TW)

(72) Inventor: HSIN-CHIANG LIN, Hsinchu (TW)

(73) Assignee: ADVANCED OPTOELECTRONIC TECHNOLOGY, INC., Hsinchu Hsien 300 (TW)

(21) Appl. No.: 13/570,223

(22) Filed: Aug. 8, 2012

(30) Foreign Application Priority Data
Dec. 30, 2011 (CN) 201110452980.5

(51) Int. Cl. H01L 33/50

(52) U.S. Cl. 257/89; 257/E33.061

(57) ABSTRACT

A light emitting diode (LED) device includes a substrate having a top surface, a first LED and a second LED arranged on the top surface of the substrate, and a lens arranged over the light emitting surface of the first and second LEDs. The first and second LEDs each have a light emitting surface away from the top surface of the substrate. A first wavelength of light emitted from the first LED is shorter than a second wavelength of light emitted from the second LED. The lens includes a convergent part located right above the second LED and a divergent part located right above the first LED.

### BACKGROUND

1. Technical Field

The disclosure relates to light emitting diode (LED) devices, and particularly to an LED device having multiple light emitting diodes, wherein light beams from the light emitting diodes can be more completely mixed to obtain a high color rendering index (CRI).

2. Discussion of Related Art

LEDs' many advantages, such as high luminosity, low operational voltage, low power consumption, compatibility with integrated circuits, faster switching, long term reliability, and environmental friendliness have promoted their wide use as a light source.

The conventional LED device generally includes at least two LEDs. The at least two LEDs generate light with different wavelengths to cooperatively obtain white light. However, when the working current is constant, LED with short wavelength light output usually has high light extraction efficiency, and LED with long wavelength light output usually has low light extraction efficiency. The long wavelength light and the short wavelength light do not mix together completely, whereby the CRI of the conventional LED device is not high. Furthermore, the light intensity distribution of the conventional LED device is not uniform. Some discrete spots thereof have distinguishably high light intensity. Such features cause the conventional LED device to be not suitable for use in illumination, which requires a light field with an even light intensity.

Therefore, what is needed is an LED device which can overcome the described limitations.

### BRIEF DESCRIPTION OF THE DRAWINGS

Many aspects of the disclosure can be better understood with reference to the following drawing. The components in the drawing are not necessarily drawn to scale, the emphasis instead being placed upon clearly illustrating the principles of the present light emitting diode device for microminiaturization. Moreover, in the drawing, like reference numerals designate corresponding parts throughout the whole view.

FIG. 1 is a cross-sectional view of an LED device in accordance with an exemplary embodiment of the present disclosure.

FIG. 2 is a graph of a light intensity distribution of the LED device of FIG. 1 with a lens of the LED device of FIG. 1 being removed.

FIG. 3 is a graph of the light intensity distribution of the LED device of FIG. 1 with the lens not removed.

### DETAILED DESCRIPTION OF EMBODIMENTS

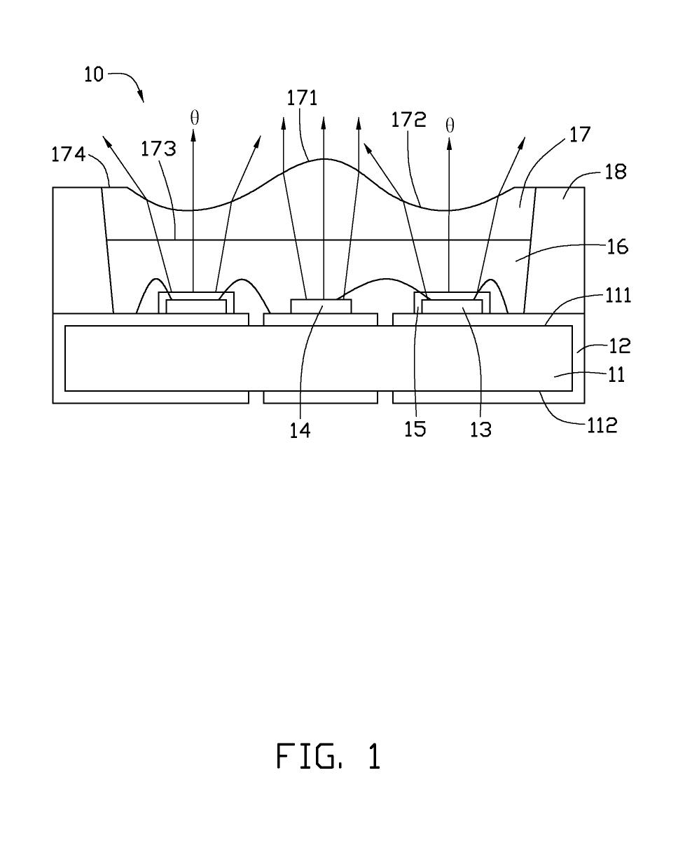

Referring to FIG. 1, an LED device 10 in accordance with an exemplary embodiment of the present disclosure is illustrated. The LED device 10 includes a substrate 11, a pair of electrodes 12 formed on two sides of the substrate 11, a plurality of first LEDs 13, a second LED 14 mounted on the substrate 11, a phosphor 15 covers each of the first LEDs 13, a reflecting cup 18 arranged on the substrate 11 and surrounding the first LEDs 13 and the second LED 14, an encapsulant 16 received in the reflecting cup 18 and covering the first LEDs 13 and the second LED 14, and a lens 17 received in the reflecting cup 18 and covering the encapsulant 16.

The substrate 11 beneficially is a single rectangular plate and has a planar top surface 111 and a planar bottom surface 112 opposite to the top surface 111. In the present embodiment, the substrate 111 is made of insulated material, such as polyphthalamide (PPA).

Each electrode 12 extends from the top surface 111 of the substrate 11 to the bottom surface 112 thereof along an outer edge of the substrate 11, whereby the LED device 10 is formed as a surface mounting type device. In the present embodiment, the electrodes 12 are made of metal with high electrical conductivity selected from a group consisting of gold, silver, copper, platinum, aluminum, nickel, tin, magnesium and combination thereof.

The first LEDs 13 and the second LED 14 are mounted on and electrically connected to the electrodes 12 in series. The second LED 14 is arranged on a central portion of the substrate 11. The first LEDs 13 surround the second LED 14. During operation, each first LED 13 emits a first light with a first wavelength, and the second LED 14 emits a second light with a second wavelength. The first wavelength of the light emitted from each first LED 13 is shorter than the second wavelength of the light emitted from the second LED 14. In the present embodiment, the first wavelength of the light emitted from each first LED 13 is in a range from 450 to 550 nm. The second wavelength of the light emitted from the second LED 14 is greater than 570 nm. The first LEDs 13 can be blue LEDs, green LEDs, or blue-green LEDs, and the second LED 14 can be a red LED. In other embodiments, the LED device 10 can include only one first LED 13 and one second LED 14, or include one first LED 13 and a plurality of second LEDs 14. The configuration of the first LEDs 13 and the second LED 14 can be adjusted according to actual requirement.

The phosphor 15 covers a light emitting surface of each of the first LEDs 13. The phosphor 15 is yellow phosphor. The phosphor 15 is excited by a part of the light emitted from the first LEDs 13 and generates a yellow color light. The generated yellow color light and another part of the light emitted from the first LEDs 13 are mixed to produce a white light.

The reflecting cup 18 is arranged on the top surface 111 of the substrate 11 and surrounds the first LEDs 13 and second LED 14. The reflecting cup 18 can be made of PPA. Part of light emitted from the first LEDs 13 and the second LED 14 are reflected out of the LED device 10 for lightening by the reflecting cup 18.

The encapsulant 16 is received in the reflecting cup 18 and covers the first LEDs 13, the second LED 14 and part of the electrodes 12 which arranged on the top surface 111 of the substrate 11. The encapsulation 16 is formed of solidified adhesive.

The lens 17 is received in the reflecting cup 18 and covers the encapsulant 16. The lens 17 includes a planar light input surface 173 connected to the encapsulant 16 and a light output surface 174 opposite to the light input surface 173. The light output surface 174 of the lens 17 includes a convergent part 171 and a plurality of divergent parts 172. In the present embodiment, the convergent part 171 is a convex surface towards outside of the LED device 10 and is just located above the second LED 14, and each divergent part 172 is a concave surface towards a corresponding first LED 13 and is just located above the corresponding first LED 13. The convergent part 171 is used for converging light emitted from the second LED 14. The divergent part 172 is used for diverging light emitted from the corresponding first LED 13. In other embodiments, the lens 17 can be arranged over the reflecting cup 18.

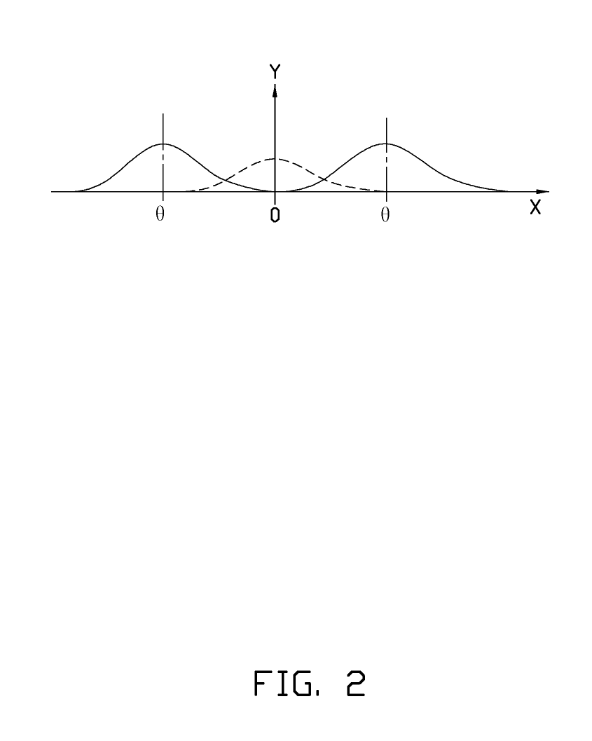

Referring to FIG. 2 also, a graph of a light intensity distribution of the LED device 10 with the lens 17 being removed is provided. X-axis represents a width of the LED device 10, and Y-axis represents the light intensity of light and extends through a center 0 of the LED device 10. The center 0 of the LED 10 device is coincidental with the center of the second LED 14. The real line at left of FIG. 2 represents the light intensity distribution of the first LED 13 arranged on the left of the second LED 14. The real line at right represents the light intensity distribution of the first LED 13 arranged on the right of the second LED 14. The broken line in middle represents the light intensity distribution of the second LED 14. It can be seen from FIG. 2 that the first LEDs 13 with short wavelength light output have higher light intensity than the second LED 14 with long wavelength light output. Furthermore, each LED 13, 14 has its respective highest light intensity at a central point thereof (0 for LED 14, θ for LEDs 13), wherein the highest light intensity of the LED 14 is lower that that of each of the LEDs 13. Without the lens 17, it can be seen from FIG. 2 that the light intensity distribution is uneven, wherein a uniform white light cannot obtained; furthermore, the light beams from the LEDs 13, 14 mix with each other only by a low degree, whereby a CRI of the light is low.

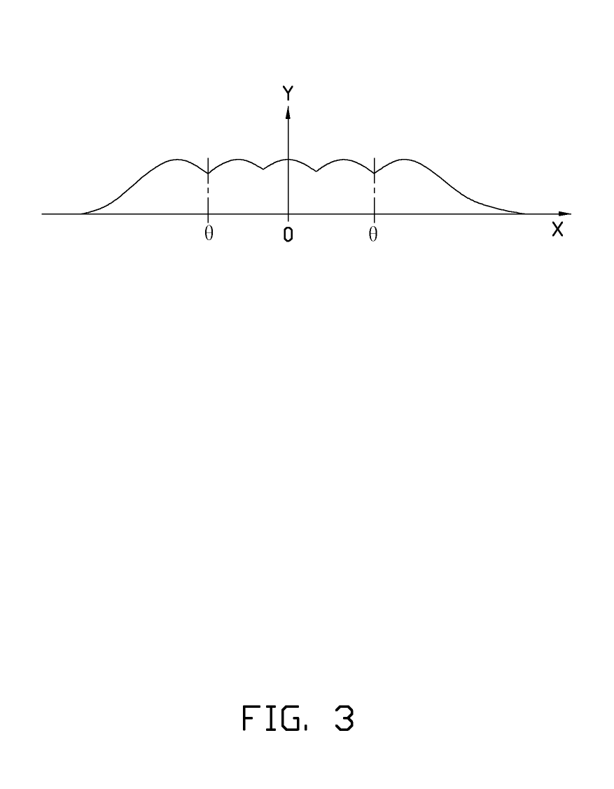

Light emitted from the first LEDs 13 and the second LED 14 are adjusted by the lens 17. The convergent part 171 converges light emitted from the second LED 14; therefore, light intensity of the second LED 14 at the original point 0 is increased. The divergent part 172 diverges light emitted from the corresponding first LED 13; therefore, light intensity from the first LEDs 13 at the central point θ is reduced. Furthermore, by the divergent parts 17, more light from the first LEDs 13 are directed sideward to mix with the light from the LED 14. Thus, the light intensity can be more evenly distributed over an entire output surface of the LED device 10. Referring to FIG. 3 also, the real line represents the light intensity distribution of the LED device 10; it can be seen from the graph that the light intensity of LED device 10 is more evenly distributed, whereby a uniform light output is obtained. Moreover, since the light beams from the LEDs 13, 14 are more completely mixed, the light from the LED device 10 can have a high CRI.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. An LED (light emitting diode) device, comprising:
a substrate having a top surface;
a first LED and a second LED arranged on the top surface of the substrate, the first and second LEDs each having a light emitting surface away from the top surface of the substrate, a first wavelength of light emitted from the first LED being shorter than a second wavelength of light emitted from the second LED; and
a lens arranged over the light emitting surfaces of the first and second LEDs, the lens comprising a convergent part just located above the second LED and a divergent part just located above the first LED.

2. The LED device of claim 1, wherein the first wavelength of light emitted from the first LED is in a range from 450 to 550 nm, and the second wavelength of light emitted from the second LED is greater than 570 nm;

3. The LED device of claim 1, wherein the lens comprises a light input surface facing the top surface of the substrate and a light output surface opposite to the light input surface, the light output surface comprising the convergent part and the divergent part.

4. The LED device of claim 3, wherein the light input surface is a planar surface.

5. The LED device of claim 1, wherein the convergent part is a convex surface towards outside of the LED device, and the divergent part is a concave surface towards the first LED.

6. The LED device of claim 1, wherein the first LED is selected from a group consisting of blue LED, green LED, and blue-green LED.

7. The LED device of claim 1, wherein the second LED is a red LED.

8. The LED device of claim 1, wherein a phosphor covers the light emitting surface of the first LED.

9. The LED device of claim 1, further comprising a reflecting cup arranged on the top surface of the substrate and surrounding the first LED and the second LED, the lens being received in the reflecting cup.

10. An LED device, comprising:
a substrate having a top surface;
a plurality of first LEDs and a second LED arranged on the top surface of the substrate, the first and second LEDs each having a light emitting surface away from the top surface of the substrate, light emitted from the first LED having a first wavelength which is in a range from 450 to 550 nm, and light emitted from the second LED having a second wavelength which is greater than 570 nm;
a lens arranged over the light emitting surfaces of the first LEDs and the second LED, the lens comprising a convergent part located right above the second LED and a plurality of divergent parts each located right above a corresponding first LED.

11. The LED device of claim 10, wherein the second LED is arranged on a central portion of the top surface, and the first LEDs surround to the second LED.

12. The LED device of claim 10, wherein the lens comprises a light input surface facing the top surface of the substrate and a light output surface opposite to the light input surface, the light output surface comprising the convergent part and the divergent parts.

13. The LED device of claim 12, wherein the light input surface is a planar surface.

14. The LED device of claim 10, wherein the convergent part is a convex surface, and each of the divergent parts is a concave surface.

15. The LED device of claim 10, wherein each of the first LEDs is selected from a group consisting of blue LED, green LED, and blue-green LED.

16. The LED device of claim 10, wherein the second LED is a red LED.

17. The LED device of claim 10, wherein a phosphor covers the light emitting surface of each of the first LEDs.
